(19) United States
(12) Patent Application Publication
(10) Pub. No.: US 2017/0371006 A1
(43) Pub. Date: Dec. 28, 2017

(54) MAGNETIC SENSOR AND CURRENT SENSOR

(71) Applicant: Alps Electric Co., Ltd., Tokyo (JP)

(72) Inventor: Yosuke IDE, Niigata-ken (JP)

(21) Appl. No.: 15/600,219

(22) Filed: May 19, 2017

(30) Foreign Application Priority Data
Jun. 23, 2016 (JP) 2016-124570

(51) Int. Cl. G01R 33/09; G01R 33/31; G01R 15/20; H01F 1/153; G01R 33/00; H01F 1/00

(52) U.S. Cl. CPC G01R 33/091; G01R 33/31; G01R 15/205; G01R 33/0082; H01F 1/0009; H01F 1/153

(57) ABSTRACT

A magnetic sensor includes a magnetoresistive effect element having a sensitivity axis in a specific direction. The magnetoresistive effect element has on a substrate, a laminate structure in which a fixed magnetic layer and a free magnetic layer are laminated with a nonmagnetic material layer interposed therebetween and includes at a side of the free magnetic layer apart from the nonmagnetic material layer, a first antiferromagnetic layer which generates an exchange coupling bias with the free magnetic layer and aligns a magnetization direction thereof in a predetermined direction in a magnetization changeable state. The free magnetic layer includes a first ferromagnetic layer in contact with the first antiferromagnetic layer to be exchange-coupled therewith and a magnetic adjustment layer at a side of the first ferromagnetic layer apart from the first antiferromagnetic layer. The magnetic adjustment layer contains at least one iron group element and at least one platinum group element.

### CLAIM OF PRIORITY

This application claims benefit of Japanese Patent Application No. 2016-124570 filed on Jun. 23, 2016, which is hereby incorporated by reference.

### BACKGROUND OF THE INVENTION

### 1. Field of the Invention

The present invention relates to a magnetic sensor and a current sensor including the magnetic sensor.

### 2. Description of the Related Art

In motor drive-technique fields for electric cars and hybrid cars, infrastructure-related fields, such as pole transformers, and the like, since a relatively large current is used, a current sensor capable of measuring a large current in a contactless manner has been required. As the current sensor described above, a current sensor using a magnetic sensor detecting an induced magnetic field from a current to be measured has been known. As a magnetic detection element for the magnetic sensor, for example, a magnetoresistive effect element, such as a giant magnetoresistive effect (GMR) element, may be mentioned.

A GMR element has as a basic structure, a laminate structure in which a fixed magnetic layer and a free magnetic layer are laminated to each other with a nonmagnetic material layer interposed therebetween. A magnetization direction of the fixed magnetic layer is fixed in one direction by an exchange coupling bias by a laminate structure of an antiferromagnetic layer and a ferromagnetic layer or by the RKKY interaction (indirect exchange interaction) by a self-pinning structure in which two ferromagnetic layers are laminated to each other with a nonmagnetic interlayer interposed therebetween. A magnetization direction of the free magnetic layer is configured to be changeable in response to an external magnetic field.

In addition, a current sensor using a magnetic sensor including a GMR element, since an induced magnetic field from a current to be measured is applied to the GMR element, a magnetization direction of a free magnetic layer is changed. In accordance with a relative angle between the magnetization direction of this free magnetic layer and that of the fixed magnetic layer, since an electric resistance of the GMR element is changed, when this electric resistance is measured, the magnetization direction of the free magnetic layer can be detected. In addition, based on the magnetization direction detected by the magnetic sensor, the magnitude and the direction of the current to be measured which generates the induced magnetic field can be obtained.

Incidentally, in an electric car or a hybrid car, the drive of a motor is controlled based on a current value in some cases, and in addition, a control method of a battery is adjusted in accordance with a current value flowing thereinto in some cases. Hence, in order to accurately detect the current value, a current sensor using a magnetic sensor is required to improve measurement accuracy of the magnetic sensor.

In order to improve the measurement accuracy of the magnetic sensor, reduction in offset, reduction in variation in output signal, and improvement in linearity (output linearity) are required to be realized. As one preferable method to respond the requirements described above, reduction in hysteresis of the GMR element of the magnetic sensor may be mentioned. As a particular example of the method to reduce the hysteresis of the GMR element, there may be mentioned a method in which by applying a bias magnetic field to a free magnetic layer, the magnetization direction thereof is aligned even in the state in which the induced magnetic field from a current to be measured is not applied.

As a method to apply the bias magnetic field to a free magnetic layer, Japanese Unexamined Patent Application Publication No. 2012-185044 has disclosed a method in which an antiferromagnetic layer which generates an exchange coupling bias with a free magnetic layer and which aligns the magnetization direction thereof in a predetermined direction in a magnetization changeable state is laminated on the free magnetic layer.

### SUMMARY OF THE INVENTION

The method described above in which the exchange coupling bias is generated by the antiferromagnetic layer has advantages, such as the uniformity in bias magnetic field, as compared to a method in which permanent magnets are disposed around a GMR element to generate the bias magnetic field. However, when the GMR element is used in a high temperature environment, the bias magnetic field by the exchange coupling bias generated in the free magnetic layer is decreased, and as a result, the detection accuracy of the GMR element may tend to decrease in some cases.

By the use of the basic technique disclosed in Japanese Unexamined Patent Application Publication No. 2012-185044 in which a single magnetic domain state is formed in the free magnetic layer based on the exchange coupling bias, the present invention provides a magnetic sensor including a magnetoresistive effect element (GMR element), the detection accuracy of which is not likely to decrease even in a high temperature (in particular, such as 85° C. or 150° C.) environment, and a current sensor including the magnetic sensor described above.

In order to solve the problem described above, through intensive research carried out by the present inventors, it was found that when the free magnetic layer is formed to have a laminate structure and to contain a nonmagnetic material so that a reduction rate (%/° C.) of a saturation magnetization of the free magnetic layer in association with an increase in temperature is increased, even in a high temperature environment, a decrease in detection sensitivity of a magnetoresistive effect element can be made unlikely to occur.

According to one aspect of the present invention made by the finding described above, there is provided a magnetic sensor which comprises a magnetoresistive effect element having a sensitivity axis in a specific direction. The magnetoresistive effect element described above has on a substrate, a laminate structure in which a fixed magnetic layer and a free magnetic layer are laminated to each other with a nonmagnetic material layer interposed therebetween and includes at a side of the free magnetic layer opposite to the side thereof facing the nonmagnetic material layer, a first antiferromagnetic layer which generates an exchange coupling bias with the free magnetic layer and which aligns the magnetization direction of the free magnetic layer in a predetermined direction in a magnetization changeable state; the free magnetic layer includes a first ferromagnetic layer provided in contact with the first antiferromagnetic layer so as to be exchange-coupled therewith and a magnetic adjustment layer at a side of the first ferromagnetic layer opposite to the side thereof facing the first antiferromagnetic layer; and the magnetic adjustment layer contains at least one iron group element and at least one platinum group element.

Since the magnetic adjustment layer contains, besides at least one iron group element having a magnetic property, at least one platinum group element having a nonmagnetic property, a saturation magnetization Ms of the magnetic adjustment layer is reduced. Hence, a saturation magnetization Ms of the free magnetic layer including the magnetic adjustment layer described above is reduced. The degree of reduction of the saturation magnetization Ms of the free magnetic layer caused by this magnetic adjustment layer is apparent at a high temperature (150° C.) than that at room temperature (25° C.). In this case, the magnitude of the exchange coupling bias generated in the free magnetic layer by exchange coupling with the first antiferromagnetic layer is inversely proportional to a magnetization amount Ms·t (t represents the thickness of the free magnetic layer) of the free magnetic layer. Hence, when the degree of reduction of the saturation magnetization Ms of the free magnetic layer in association with the increase in temperature is increased, the degree of reduction of the magnitude of the exchange coupling bias generated in the free magnetic layer in association with the increase in temperature can be decreased. Hence, when the free magnetic layer includes the magnetic adjustment layer described above, a magnetic sensor, the detection accuracy of which is not likely to decrease even in a high temperature environment, can be obtained.

In the magnetic sensor described above, a Curie temperature Tcₐ of the magnetic adjustment layer is preferably lower than a Curie temperature Tc₁ of the first ferromagnetic layer in some cases. In the case described above, the reduction of the saturation magnetization Ms of the free magnetic layer is likely to be apparent as the temperature is increased.

In the magnetic sensor described above, a reduction rate R_{Ms} of the saturation magnetization Ms of the magnetic adjustment layer obtained when the temperature thereof is increased from 25° C. to 150° C. is preferably larger than a reduction rate R_{Ms0} of the saturation magnetization Ms of a reference layer obtained when the temperature thereof is increased from 25° C. to 150° C., the reference layer being formed by substituting every platinum group element contained in the magnetic adjustment layer with the iron group element.

The content of the platinum group element in a material forming the magnetic adjustment layer of the magnetic sensor described above is preferably 40 percent by atom or less in some cases. Since the content of the platinum group element is 40 percent by atom or less, even in a high temperature (such as 85° C.) environment, an exchange coupling bias having a magnitude approximately equivalent to that obtained in a room temperature (25° C.) environment may be obtained in some cases.

The content of the platinum group element in the material forming the magnetic adjustment layer of the magnetic sensor described above is preferably 10 percent by atom or more in some cases. Since the content of the platinum group element is 10 percent by atom or more, an effect (suppression of the decrease in detection accuracy in a high temperature environment) obtained by the formation of the magnetic adjustment layer may be more stably obtained in some cases.

The free magnetic layer of the magnetic sensor described above may further include a second ferromagnetic layer disposed at a side of the magnetic adjustment layer opposite to the side thereof facing the first ferromagnetic layer.

In the magnetic sensor described above, the nonmagnetic material layer may contain Cu, and a surface of the free magnetic layer in contact with the nonmagnetic material layer may be formed of a surface of a ferromagnetic layer containing Co and Fe.

The first antiferromagnetic layer described above may contain a platinum group element and manganese (Mn). The first antiferromagnetic layer described above may be formed from at least one of IrMn and PtMn.

The fixed magnetic layer may be formed by laminating a first magnetic layer and a second magnetic layer in contact with the nonmagnetic material layer to each other with a nonmagnetic interlayer interposed therebetween and may have a self-pinning structure in which the magnetization of the first magnetic layer and the magnetization of the second magnetic layer are fixed in antiparallel to each other.

The magnetoresistive effect element may further include at a side of the fixed magnetic layer opposite to the side thereof facing the nonmagnetic material layer, a second antiferromagnetic layer which generates an exchange coupling bias with the fixed magnetic layer and which aligns the magnetization direction of the fixed magnetic layer in a predetermined direction.

In the laminate structure described above, the free magnetic layer may be laminated so as to be located between the fixed magnetic layer and the substrate, or the fixed magnetic layer may be laminated so as to be located between the free magnetic layer and the substrate.

As another aspect of the present invention, a current sensor including the magnetic sensor described above is provided.

According to the present invention, although a method in which the exchange coupling bias is generated in the free magnetic layer is used, a magnetic sensor including a magnetoresistive effect element, the detection accuracy of which is not likely to decrease even in a high temperature environment, can be provided. In addition, a current sensor using the magnetic sensor as described above is also provided.

### BRIEF DESCRIPTION OF THE DRAWINGS

FIG. 1 is an enlarged plan view of a magnetoresistive effect element forming a magnetic sensor according to one embodiment of the present invention;

FIG. 2 is a cross-sectional view taken along the line II-II shown in FIG. 1;

FIG. 3 is a cross-sectional view taken along the line II-II shown in FIG. 1 in the case in which the magnetoresistive effect element forming the magnetic sensor shown in FIG. 1 has a three-layered free magnetic layer instead of a two-layered free magnetic layer;

FIG. 4 is a cross-sectional view taken along the line II-II shown in FIG. 1 in the case in which the magnetoresistive effect element forming the magnetic sensor shown in FIG. 1 has an exchange coupling type fixed magnetic layer instead of a self-pinning type fixed magnetic layer;

FIG. 5 is a graph showing the relationship between a saturation magnetization Ms and a platinum content of a magnetic adjustment layer;

FIG. 6 is a graph showing the relationship between a Curie temperature Tcₐ and the platinum content of the magnetic adjustment layer;

FIG. 7 is a graph showing the relationship between a reduction rate R_{Ms} of a saturation magnetization Ms and the Curie temperature Tcₐ of the magnetic adjustment layer;

FIG. 8 is a graph showing the temperature dependence of an exchange coupling bias Hex normalized by that at 25° C.;

FIG. 9 is a graph showing the relationship between a zero-magnetic field hysteresis ZH and the platinum content of the magnetic adjustment layer; and

FIG. 10 is a graph showing the relationship of the platinum content of the magnetic adjustment layer with an exchange coupling bias Hex at 85° C. and a zero-magnetic field hysteresis ZH1 at 25° C. after application of a high magnetic field.

### DESCRIPTION OF THE PREFERRED EMBODIMENTS

### 1. Magnetic Sensor

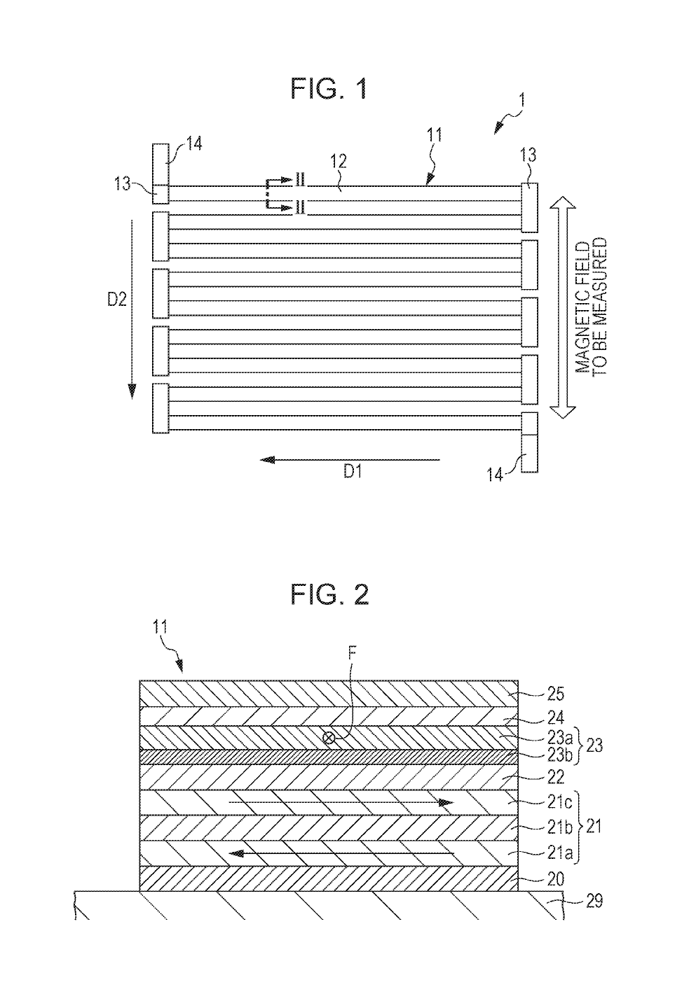

FIG. 1 is a schematic view (plan view) of a magnetic sensor according to one embodiment of the present invention, and FIG. 2 is a cross-sectional view taken along the line II-II shown in FIG. 1.

A magnetic sensor 1 according to one embodiment of the present invention includes as shown in FIG. 1, a magnetoresistive effect element 11 having a stripe-shaped GMR element. The magnetoresistive effect element 11 has a shape (meandering shape) in which belt-shaped long patterns 12 (strips) are arranged so as to be parallel to each other in a stripe longitudinal direction D1 (hereinafter, also simply referred to as “longitudinal direction D1” in some cases). In this meandering-shaped magnetoresistive effect element 11, a sensitivity axis direction is a direction D2 (hereinafter, also simply referred to as “width direction D2” in some cases) orthogonal to the longitudinal direction D1 of the long pattern 12. Hence, when the magnetic sensor 1 including this meandering-shaped magnetoresistive effect element 11 is used, a magnetic field to be measured and a cancellation magnetic field are applied so as to be along the width direction D2.

Among the belt-shaped long patterns 12 arranged in parallel to each other, long patterns 12 other than those located at ends in an arrangement direction are each connected at the end portion thereof to a belt-shaped long pattern 12 located at the position closest thereto with an electric conductive portion 13 provided therebetween. The long patterns 12 located at the ends in the arrangement direction are each connected to a connection terminal 14 with an electric conductive portion 13 provided therebetween. Accordingly, the magnetoresistive effect element 11 has the structure in which between the two connection terminals 14, the long patterns 12 are connected to each other in series with the electric conductive portions 13 provided therebetween. Although not being limited to nonmagnetic or magnetic, the electric conductive portions 13 and the connection terminals 14 are each preferably formed of a material having a low electric resistance. The magnetic sensor 1 is able to output a signal from the magnetoresistive effect element 11 through the two connection terminals 14. The signal from the magnetoresistive effect element 11 output through the connection terminals 14 is input into a computing portion which is not shown, and in the computing portion, an electric power to be measured is calculated based on the signal described above.

As shown in FIG. 2, the long patterns 12 of the magnetoresistive effect element 11 are each formed so that a seed layer 20, a fixed magnetic layer 21, a nonmagnetic material layer 22, a free magnetic layer 23, a first antiferromagnetic layer 24, and a protective layer 25 are laminated in this order from the bottom on a substrate 29 with an insulating layer or the like (not shown) provided thereon. A film formation method of those layers is not limited, and for example, the film formation may be performed by sputtering.

The seed layer 20 is formed, for example, of NiFeCr or Cr.

The fixed magnetic layer 21 has a self-pinning structure including a first magnetic layer 21a, a second magnetic layer 21c, and a nonmagnetic interlayer 21b located therebetween. As shown in FIG. 2, a fixed magnetization direction of the first magnetic layer 21a and a fixed magnetization direction of the second magnetic layer 21c are antiparallel to each other. In addition, the fixed magnetization direction of the second magnetic layer 21c is a fixed magnetization direction of the fixed magnetic layer 21, that is, is the sensitivity axis direction.

As shown in FIG. 2, the first magnetic layer 21a is formed on the seed layer 20, and the second magnetic layer 21c is formed in contact with the nonmagnetic material layer 22 which will be described later. The first magnetic layer 21a is preferably formed of a CoFe alloy which is a high coercive material as compared to that of the second magnetic layer 21c.

The second magnetic layer 21c in contact with the nonmagnetic material layer 22 is a layer which contributes to a magnetoresistive effect (in particular, the GMR effect), and as the second magnetic layer 21c, a magnetic material which can increase the difference in mean free path between a conduction electron having an up spin and a conduction electron having a down spin may be selected.

In the magnetoresistive effect element 11 shown in FIG. 2, the difference in magnetization amount (saturation magnetization Ms·film thickness t) between the first magnetic layer 21a and the second magnetic layer 21c is adjusted to be substantially zero.

Since having a self-pinning structure, the fixed magnetic layer 21 of the magnetoresistive effect element 11 shown in FIG. 2 includes no antiferromagnetic layer. Accordingly, the temperature characteristics of the magnetoresistive effect element 11 are not restricted by a blocking temperature of the antiferromagnetic layer.

In order to increase a magnetization fixing force of the fixed magnetic layer 21, it has been believed important to increase a coercive force Hc of the first magnetic layer 21a, to adjust the difference in magnetization amount between the first magnetic layer 21a and the second magnetic layer 21c to substantially zero, and to increase an antiparallel coupling magnetic field by the RKKY interaction generated between the first magnetic layer 21a and the second magnetic layer 21c by further adjusting the thickness of the nonmagnetic interlayer 21b. When the adjustments described above are appropriately performed, the magnetization of the fixed magnetic layer 21 is more tightly fixed without being influenced by an external magnetic field.

The nonmagnetic material layer 22 is formed of Cu (copper) or the like.

The free magnetic layer 23 of the magnetoresistive effect element 11 shown in FIG. 2 is formed of a first ferromagnetic layer 23a and a magnetic adjustment layer 23b. The first ferromagnetic layer 23a is formed to have a single layer structure or a laminate structure using a ferromagnetic material, such as NiFe or CoFe, and is exchange-coupled with the first antiferromagnetic layer 24.

The magnetic adjustment layer 23b is a layer provided at a side of the first ferromagnetic layer 23a opposite to the side thereof facing the first antiferromagnetic layer 24. The magnetic adjustment layer 23b contains at least one iron group element (in particular, at least one of Fe, Co, and Ni) and at least one platinum group element (in particular, for example, at least one of Pt, Pd, Rh, Ir, Ru, and Os). The magnetic adjustment layer 23b decreases the saturation magnetization Ms of the free magnetic layer 23 and, as a result, increases the magnitude of an exchange coupling bias Hex as described below.

The magnitude of the exchange coupling bias Hex is proportional to energy (exchange coupling energy) Jk of the exchange coupling between the free magnetic layer 23 and the first antiferromagnetic layer 24 and is inversely proportional to the magnetization amount Ms·t (t represents the thickness of the free magnetic layer 23) of the free magnetic layer 23. That is, the following formula holds:

Hex=Jk/(Ms·t)

As apparent from the above formula, when the saturation magnetization Ms of the free magnetic layer 23 is decreased, the magnitude of the exchange coupling bias Hex can be increased. In this case, when the temperature of the magnetoresistive effect element 11 is increased, as a general tendency, the exchange coupling energy Jk is decreased, and the saturation magnetization Ms of the free magnetic layer 23 is also decreased. Since the magnetic adjustment layer 23b contains a platinum group element, the saturation magnetization Ms of the free magnetic layer 23 at room temperature (25° C.) can be decreased, and furthermore, the degree of reduction of the saturation magnetization Ms at a high temperature (in particular, such as 85° C. or 150° C.) can be increased. As shown in Examples which will be described later, when the content of the platinum group element in a material forming the magnetic adjustment layer 23b is increased, a Curie temperature Tcₐ (unit: ° C.) of the magnetic adjustment layer 23b is decreased, and this decrease is believed to have a certain influence on the increase in degree of reduction of the saturation magnetization Ms described above. In other words, it may also be said that the Curie temperature Tcₐ of the magnetic adjustment layer 23b is preferably lower than a Curie temperature Tc₁ of the first ferromagnetic layer 23a in some cases.

As described above, since the free magnetic layer 23 includes the magnetic adjustment layer 23b, the saturation magnetization Ms of the free magnetic layer 23 in a high temperature environment can be significantly reduced, and as a result, the decrease in magnitude of the exchange coupling bias Hex in a high temperature environment can be moderated.

The function of the magnetic adjustment layer 23b included in the free magnetic layer 23 may be explained as follows. That is, a reduction rate R_{Ms} of the saturation magnetization Ms of the magnetic adjustment layer 23b obtained when the temperature thereof is increased from 25° C. to 150° C. may be set to be larger than a reduction rate R_{Ms)} of the saturation magnetization Ms of a reference layer obtained when the temperature of the reference layer in which every platinum group element contained in the magnetic adjustment layer 23b is substituted with the iron group element is increased from 25° C. to 150° C. The reduction rate (unit: %) of the saturation magnetization Ms can be represented by the following formula.

Reduction rate=(saturation magnetization Ms at 25° C.-saturation magnetization Ms at 150° C.)/(saturation magnetization Ms at 25° C.)×100

In particular, although the reduction rate R_{Ms0} of the saturation magnetization Ms of the reference layer is generally 10% or less, the reduction rate R_{Ms} of the saturation magnetization Ms of the magnetic adjustment layer 23b of the magnetic sensor 1 according to one embodiment of the present invention is more than 10%. In order to more stably realize the moderate decrease in magnitude of the exchange coupling bias Hex in a high temperature environment, the above reduction rate R_{Ms} is preferably 15% or more in some cases, more preferably 20% or more in some cases, further preferably 25% or more in some cased, and particularly preferably 30% or more in some cases. When the reduction rate R_{Ms} described above is excessively increased, the saturation magnetization Ms of the magnetic adjustment layer 23b is extremely decreased, and in order to appropriately secure the magnetization amount (Ms·t) of the free magnetic layer 23 including the magnetic adjustment layer 23b, in particular, the thickness of the magnetic adjustment layer 23b is required to be increased; hence, for example, the productivity may be decreased in some cases. Accordingly, the reduction rate R_{Ms} described above is preferably 95% or less, more preferably 90% or less, further preferably 85% or less, particularly preferably 80% or less, and extremely preferably 75% or less.

As described above, since the magnitude of the exchange coupling bias Hex is appropriately maintained even in a high temperature environment, the increase in zero-magnetic field hysteresis of the magnetic sensor 1 can be suppressed. Hence, even when the magnetic sensor 1 according to this embodiment is used in a high temperature environment, the detection accuracy thereof is not likely to decrease.

As long as the above function of the magnetic adjustment layer 23b is obtained, the content of the platinum group element in the material forming the magnetic adjustment layer 23b may be arbitrarily determined. In order to more stably realize the above function of the magnetic adjustment layer 23b, the content of the platinum group element in the material forming the magnetic adjustment layer 23b is preferably 10 percent by atom or more in some cases. From this point of view, the content of the platinum group element in the material forming the magnetic adjustment layer 23b is more preferably 15 percent by atom or more in some cases and particularly preferably 20 percent by atom or more in some cases.

In order to stably avoid an excessive increase in thickness of the free magnetic layer 23, the content of the platinum group element in the material forming the magnetic adjustment layer 23b is preferably 45 percent by atom or less in some cases. From the point described above, the content of the platinum group element in the material forming the magnetic adjustment layer 23b is particularly preferably 40 percent by atom or less in some cases.

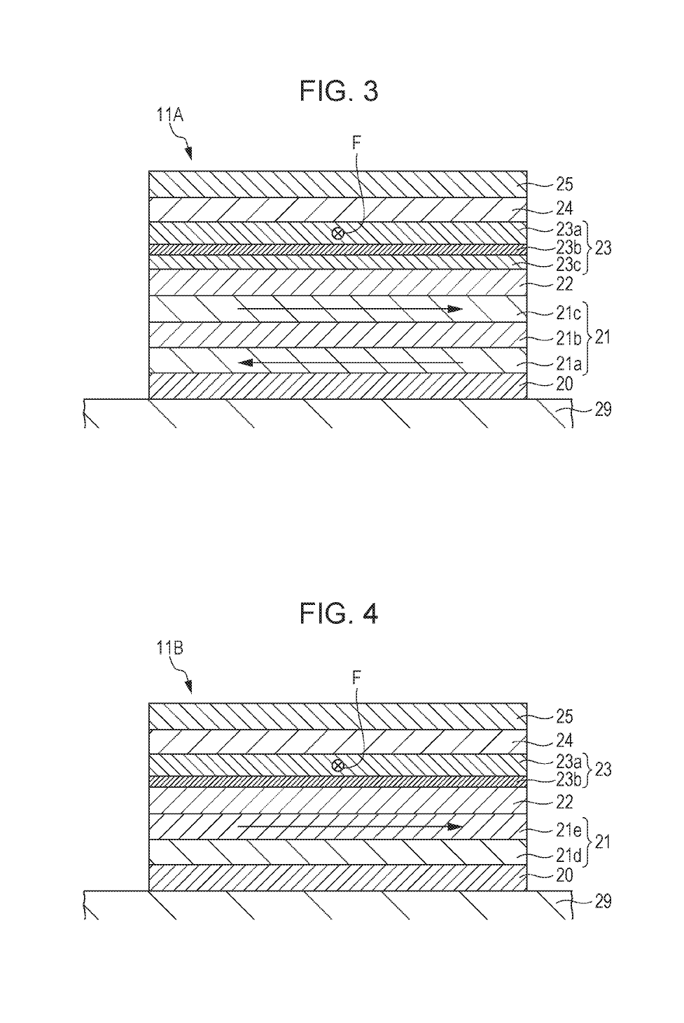

FIG. 3 is a schematic cross-sectional view showing another example of the structure of the magnetoresistive effect element according to one embodiment of the present invention. A free magnetic layer 23 of a magnetoresistive effect element 11A shown in FIG. 3 further includes, besides a first ferromagnetic layer 23a and a magnetic adjustment layer 23b, a second ferromagnetic layer 23c provided at a side of the magnetic adjustment layer 23b (side facing a nonmagnetic material layer 22) opposite to the side thereof facing the first ferromagnetic layer 23a. The second ferromagnetic layer 23c may be provided in order to adjust the magnetization amount (Ms·t) of the free magnetic layer 23. The second ferromagnetic layer 23c may also be provided in order to prevent the diffusion of substances contained in a material forming the nonmagnetic material layer 22 to other layers forming the free magnetic layer 23. For the purpose described above, in the case in which the nonmagnetic material layer 22 contains Cu, the surface of the free magnetic layer 23 in contact with the nonmagnetic material layer 22 is formed of a surface of a ferromagnetic layer containing Co and Fe and in particular, is formed of a surface of a layer formed of Co₉₀Fe₁₀, so that the diffusion of Cu into the free magnetic layer 23 can be prevented.

The thickness t of the free magnetic layer 23 and the thicknesses of the individual layers which are the constituent elements thereof are not particularly limited. When the thickness t of the free magnetic layer 23 is excessively small, the magnetization amount (Ms·t) of the free magnetic layer 23 is excessively decreased, and as the magnetic sensor 1, the detection accuracy thereof may be degraded in some cases in association with the increase in hysteresis. When the thickness t of the free magnetic layer 23 is excessively large, the productivity of the free magnetic layer 23 may be degraded in some cases.

A material forming the first antiferromagnetic layer 24 is not particularly limited. For example, a material containing a platinum group element and Mn may be mentioned, and as a particular example, IrMn and PtMn may be mentioned. The first antiferromagnetic layer 24 may be preferably formed from at least one of IrMn and PtMn in some cases.

A material forming the protective layer 25 is not particularly limited. For example, Ta (tantalum) may be mentioned. A magnetization direction F of the free magnetic layer 23 of the magnetoresistive effect element 11 shown in FIG. 2 indicates an initial magnetization direction and is aligned in the direction orthogonal to a fixed magnetization direction (fixed magnetization direction of the second magnetic layer 21c) of the fixed magnetic layer 21.

In the magnetoresistive effect element 11 shown in FIG. 2 and the magnetoresistive effect element 11A shown in FIG. 3, although the first antiferromagnetic layer 24 is formed over the entire upper surface of the free magnetic layer 23, the structure is not limited thereto, and the first antiferromagnetic layer 24 may be formed discontinuously on the upper surface of the free magnetic layer 23. However, when the first antiferromagnetic layer 24 is formed over the entire surface of the free magnetic layer 23, the entire free magnetic layer 23 can be appropriately formed to have a single magnetic domain structure in one direction, and the hysteresis can be further reduced, so that the measurement accuracy can be preferably improved.

In the magnetoresistive effect element 11 shown in FIG. 2 and the magnetoresistive effect element 11A shown in FIG. 3, although the fixed magnetic layer 21 has a self-pinning structure, the structure is not limited thereto. For example, as is the case of a magnetoresistive effect element 11B shown in FIG. 4, a fixed magnetic layer 21 thereof may have a laminate structure of a second antiferromagnetic layer 21d and a ferromagnetic layer 21e and may be magnetized by magnetizing the ferromagnetic layer 21e in a specific direction (direction to a right side along the plane of FIG. 4) by exchange coupling with the second antiferromagnetic layer 21d.

### 2. Method for Manufacturing Magnetic Sensor

A method for manufacturing a magnetic sensor according to one embodiment of the present invention is not limited. According to the following method, the magnetic sensor according to this embodiment may be efficiently manufactured.

After the seed layer 20 is formed on the substrate 29 with an insulating layer not shown in FIG. 2 interposed therebetween, the fixed magnetic layer 21 having a self-pinning structure is laminated on the seed layer 20. In particular, as shown in FIG. 2, the first magnetic layer 21a, the nonmagnetic interlayer 21b, and the second magnetic layer 21c are sequentially laminated to each other. Although the film formation method of each layer is not limited, sputtering may be mentioned by way of example. Since the first magnetic layer 21a is formed with application of a magnetic field so as to be magnetized along the width direction D2 shown in FIG. 1, by the RKKY interaction, the second magnetic layer 21c can be strongly magnetized in a direction antiparallel to the magnetization direction of the first magnetic layer 21a. In a subsequent manufacturing process, even when a magnetic field is applied to the second magnetic layer 21c thus magnetized in a direction opposite to the magnetization direction thereof, without receiving any influence therefrom, the state magnetized in the width direction D2 can be maintained.

Next, the nonmagnetic material layer 22 is laminated on the fixed magnetic layer 21. The lamination method of the nonmagnetic material layer 22 is not limited, and for example, sputtering may be mentioned.

Subsequently, while a magnetic field in a direction along the longitudinal direction D1 is applied, the free magnetic layer 23, the first antiferromagnetic layer 24, and the protective layer 25 are sequentially laminated on the nonmagnetic material layer 22. The lamination method for those layers is not limited, and for example, sputtering may be mentioned. Since the magnetic-field film formation is performed as described above, the exchange coupling bias is generated with the first antiferromagnetic layer 24 in a direction along the magnetization direction of the free magnetic layer 23. In addition, during the film formation of those layers, although the magnetic field is also applied to the fixed magnetic layer 21, since the fixed magnetic layer 21 has a pinning structure based on the RKKY interaction, the magnetization direction thereof is not changed after this magnetic field is applied. When the magnetic adjustment layer 23b of the free magnetic layer 23 is formed from NiFePt or the like by simultaneous film formation using an iron group element and a platinum group element, a film formation rate (in particular, a sputtering rate may be mentioned) of the iron group element and a film formation rate (in particular, a sputtering rate may be mentioned) of the platinum group element are adjusted, so that an alloy composition of the magnetic adjustment layer 23b may be adjusted.

In this method, when an InMn-based material is used as the material forming the first antiferromagnetic layer 24, by magnetic-field film formation without performing any particular heat treatment, the magnetization direction of the first antiferromagnetic layer 24 can be aligned. Hence, through the entire process of forming the magnetoresistive effect element 11, a process can be carried out without performing any magnetic-field annealing treatment. When the manufacturing process of the magnetoresistive effect element 11 is performed by a magnetic-field annealing-free process, magnetoresistive effect elements 11 having different sensitivity axes (the case in which the magnetization directions are opposite to each other is also included) can be easily formed on the same substrate 29. In the case in which the manufacturing process of the magnetoresistive effect element 11 requires a magnetic-field annealing treatment, when the magnetic-field annealing treatment is performed a plurality of times, the effect of a magnetic-field annealing treatment previously performed is decreased, and the magnetization direction may be difficult to be appropriately set in some cases.

After the free magnetic layer 23 and the first antiferromagnetic layer 24 are laminated by the magnetic-field film formation as described above, the protective layer 25 is finally laminated. The lamination method of the protective layer 25 is not limited, and sputtering may be mentioned as a particular example.

A removing treatment (milling) is performed on the laminate structural body obtained by the film formation process described above, so that the long patterns 12 arranged along the width direction D2 are formed. The electric conductive portions 13 connecting those long patterns 12 and the connection terminals 14 connected to the electric conductive portions 13 are formed, so that the magnetoresistive effect element 11 having a meandering shape shown in FIG. 1 is obtained.

3. Current sensor

The magnetic sensor including the magnetoresistive effect element according to one embodiment of the present invention may be preferably used as a current sensor. Although the current sensor described above may include only one magnetoresistive effect element, as disclosed in Japanese Unexamined Patent Application Publication No. 2012-185044, a bridge circuit is preferably formed using four elements so as to improve the measurement sensitivity. The method for manufacturing the magnetoresistive effect element according to one embodiment of the present invention includes no magnetic-field annealing treatment in one preferable example, and hence, a plurality of magnetoresistive effect elements may be easily formed on the same substrate.

As a particular example of the current sensor according to one embodiment of the present invention, a magnetic proportional current sensor and a magnetic balance current sensor may be mentioned.

The magnetic proportional current sensor is a formed using at least one magnetoresistive effect element according to one embodiment of the present invention (which is a magnetoresistive effect element having a laminate structure in which a fixed magnetic layer and a free magnetic layer are laminated to each other with a nonmagnetic material layer interposed therebetween; the magnetoresistive effect element includes at a side of the free magnetic layer opposite to the side thereof facing the nonmagnetic material layer, a first antiferromagnetic layer which generates an exchange coupling bias with the free magnetic layer and aligns a magnetization direction of the free magnetic layer in a predetermined direction in a magnetization changeable state; the free magnetic layer includes a first ferromagnetic layer provided in contact with the first antiferromagnetic layer so as to be exchange-coupled therewith and a magnetic adjustment layer provided at a side of the first ferromagnetic layer opposite to the side thereof facing the first antiferromagnetic layer; and the magnetic adjustment layer contains at least one iron group element and at least one platinum group element) and has a magnetic field detection bridge circuit including two outputs which generate a potential difference in accordance with the induced magnetic field from a current to be measured. In addition, in the magnetic proportional current sensor, by the potential difference output from the magnetic field detection bridge circuit in accordance with the induced magnetic field, the current to be measured is measured.

The magnetic balance current sensor is formed from at least one magnetoresistive effect element according to one embodiment of the present invention and includes a magnetic field detection bridge circuit having two outputs which generate a potential difference in accordance with the induced magnetic field from a current to be measured and a feedback coil which is disposed in the vicinity of the magnetoresistive effect element and which generates a cancellation magnetic field compensating for the induced magnetic field. In addition, in the magnetic balance current sensor, the voltage is applied to the feedback coil in accordance with the potential difference, and based on a current flowing through the feedback coil in a balance state in which the cancellation magnetic field compensates for the induced magnetic field, the current to be measured is measured.

Those embodiments have been described in order to facilitate the understanding of the present invention and are not described to limit the present invention. Hence, it is to be understood that the constituent elements disclosed in the above embodiments includes all design changes and equivalents which belong to the technical scope of the present invention.

For example, although having a so-called bottom pin structure in which the fixed magnetic layer 21 is laminated so as to be located between the free magnetic layer 23 and the substrate 29, the magnetoresistive effect elements 11, 11A, and 11B shown in FIGS. 2 to 4 each may have a so-called top pin structure in which a free magnetic layer is laminated so as to be located between a fixed magnetic layer and a substrate.

### EXAMPLES

Hereinafter, although the present invention will be described in more detail with reference to Examples and the like, the scope of the present invention is not limited thereto.

### Comparative Example 1

On a substrate having an insulating film, a seed layer: NiFeCr (42)/fixed magnetic layer [first magnetic layer: Co₄₀Fe₆₀ (19)/nonmagnetic interlayer: Ru (3.6)/second magnetic layer: Co₉₀Fe₁₀ (24)]/nonmagnetic material layer: Cu (20)/free magnetic layer {[second ferromagnetic layer: [Co₉₀Fe₁₀(10)/Ni_{81.5}Fe_{18.5} (10)]/reference layer: Ni_{81.5}Fe_{18.5} (50)/first ferromagnetic layer: Ni_{81.5}Fe_{18.5} (10)]/first antiferromagnetic layer: Ir₂₂Mn₇₈ (60)/protective layer: Ta (100) were sequentially laminated to each other from the bottom, so that a relative laminate structural body was obtained. The numerical value in the parentheses indicates the layer thickness, and the unit thereof is A.

### Examples 1 to 4

On a substrate having an insulating film, a seed layer: NiFeCr (42)/fixed magnetic layer [first magnetic layer: Co₄₀Fe₆₀ (19)/nonmagnetic interlayer: Ru (3.6)/second magnetic layer: Co₉₀Fe₁₀ (24)]/nonmagnetic material layer: Cu (20)/free magnetic layer {second ferromagnetic layer: [Co₉₀Fe₁₀ (10)/Ni_{81.5}Fe_{18.5} (10)]/magnetic adjustment layer: (Ni_{81.5}Fe_{18.5})₁₀₀₋ₓPtₓ (Y)/first ferromagnetic layer: Ni_{81.5}Fe_{18.5} (10)}/first antiferromagnetic layer: Ir₂₂Mn₇₈ (60)/protective layer: Ta (100) were sequentially laminated to each other from the bottom, so that a laminate structural body was obtained. The numerical value in the parentheses indicates the layer thickness, and the unit thereof is Å.

In addition, Y (thickness of the magnetic adjustment layer) was set so that when×(content of Pt in the magnetic adjustment layer) was changed, the magnetization amount (Ms·t) of the magnetic adjustment layer was equivalent to the magnetization amount (Ms·t) of the reference layer. In particular, Y (thickness of the magnetic adjustment layer) was set as shown in Table 1.

TABLE 1

| | Pt | Layer | Ms at | Magnetization |
|---|---|---|---|---|
| | (Percent by | thickness | 25° C. | amount |
| | atom) | (Å) | (T) | (Ms · t) |
| Comparative | 0 | 50 | 1.09 | 54.5 |
| Example 1 | | | | |
| Example 1 | 20 | 70 | 0.78 | 54.5 |
| Example 2 | 30 | 90 | 0.62 | 55.7 |
| Example 3 | 40 | 120 | 0.45 | 53.4 |
| Example 4 | 50 | 240 | 0.24 | 57.6 |

In Table 1, the platinum content, the layer thickness, the saturation magnetization Ms at 25° C., and the magnetization amount (Ms·t) of the magnetic adjustment layer (reference layer of Comparative Example) of each example are shown. The magnetization amount was obtained by calculation using the layer thickness and the saturation magnetization Ms at 25° C.

### Measurement Example 1

### Measurement of Reduction Rate R_{Ms} of Saturation Magnetization Ms

The saturation magnetizations Ms (unit: T) at 25° C. and 150° C. of the reference layer of Comparative Example 1 and the saturation magnetizations Ms at 25° C. and 150° C. of the magnetic adjustment layer of each of Examples 1 to 4 were measured. From the data thus obtained, the reduction rate R_{Ms} of the saturation magnetization Ms was obtained. In addition, the Curie temperatures of the materials forming the reference layer and each magnetic adjustment layer were measured. The results are shown in Table 2.

TABLE 2

| | | | | Curie |
|---|---|---|---|---|
| | | | | temper- |
| | Ms at | Ms at | | ature |
| | 25° C. | 150° C. | R_{Ms} | Tcₐ |
| | (T) | (T) | (%) | (° C.) |
| Comparative | 1.09 | 1.02 | 6.46 | 580 |
| Example 1 | | | | |
| Example 1 | 0.78 | 0.55 | 29.4 | 372 |
| Example 2 | 0.62 | 0.32 | 48.3 | 275 |
| Example 3 | 0.45 | 0.12 | 73.0 | 162 |
| Example 4 | 0.24 | 0.00 | 100 | 45 |

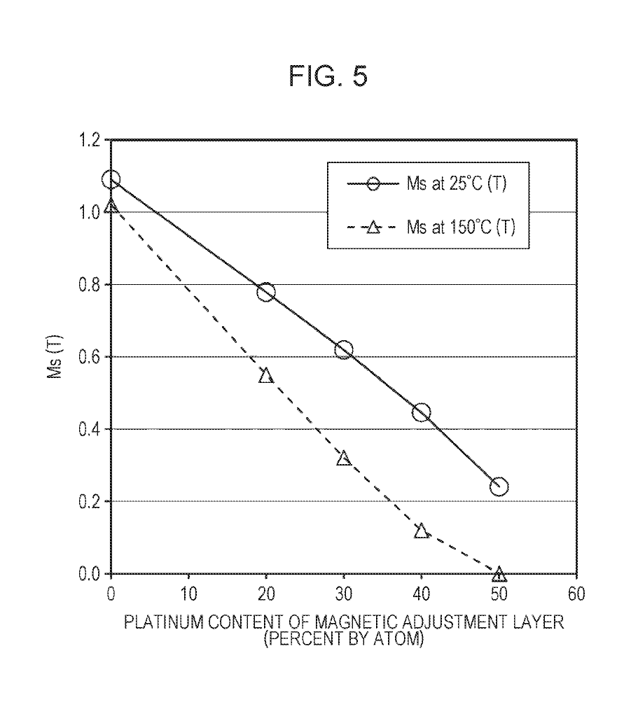

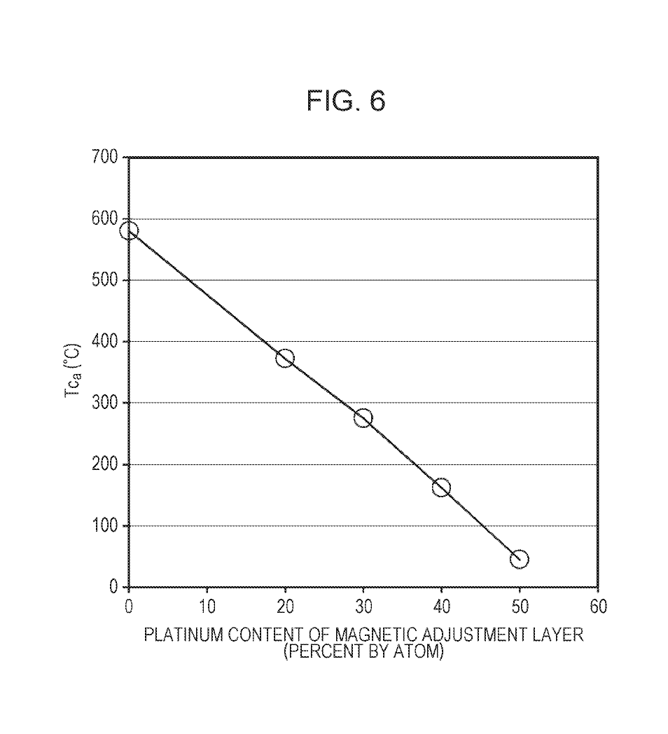

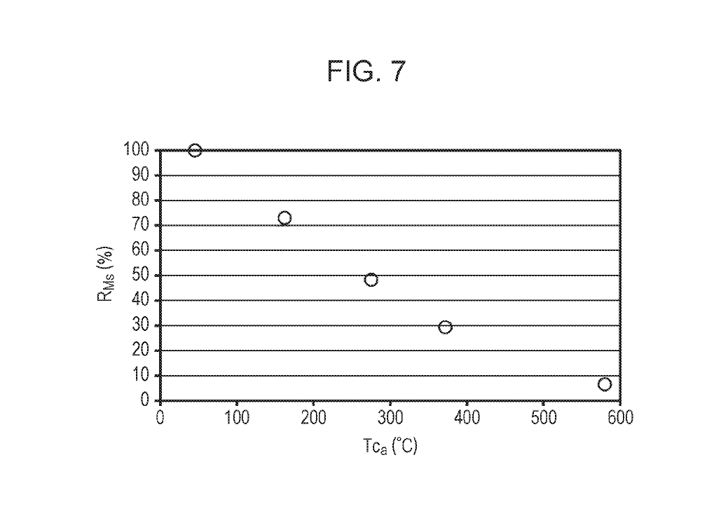

As shown in Table 2, in the magnetic adjustment layers according to Examples, the reduction rate R_{Ms} of the saturation magnetization Ms was more than 10%. FIG. 5 is a graph showing the relationship between the saturation magnetization Ms and the platinum content of the magnetic adjustment layer. As shown in FIG. 5, compared to the case measured at 25° C., in the case measured at 150° C., it was confirmed that the degree of reduction of the saturation magnetization Ms in association with the increase in platinum content was increased. FIG. 6 is a graph showing the relationship between the Curie temperature Tcₐ and the platinum content of the magnetic adjustment layer. As shown in FIG. 6, it was confirmed that the Curie temperature Tcₐ was decreased in association with the increase in platinum content, and that when the platinum content was approximately 50 percent by atom, the Curie temperature Tcₐ was decreased to approximately room temperature. FIG. 7 is a graph showing the relationship between the reduction rate R_{Ms} of the saturation magnetization Ms and the Curie temperature Tcₐ of the magnetic adjustment layer. As shown in FIG. 7, it was found that the reduction rate R_{Ms} of the saturation magnetization Ms had a high negative correlation with the Curie temperature Tcₐ of the magnetic adjustment layer (correlation factor was −0.999). Hence, it was confirmed that by controlling the Curie temperature Tcₐ of the material forming the magnetic adjustment layer, the reduction rate R_{Ms} of the saturation magnetization Ms of the magnetic adjustment layer could be adjusted.

### Measurement Example 2

### Measurement of Exchange Coupling Bias Hex

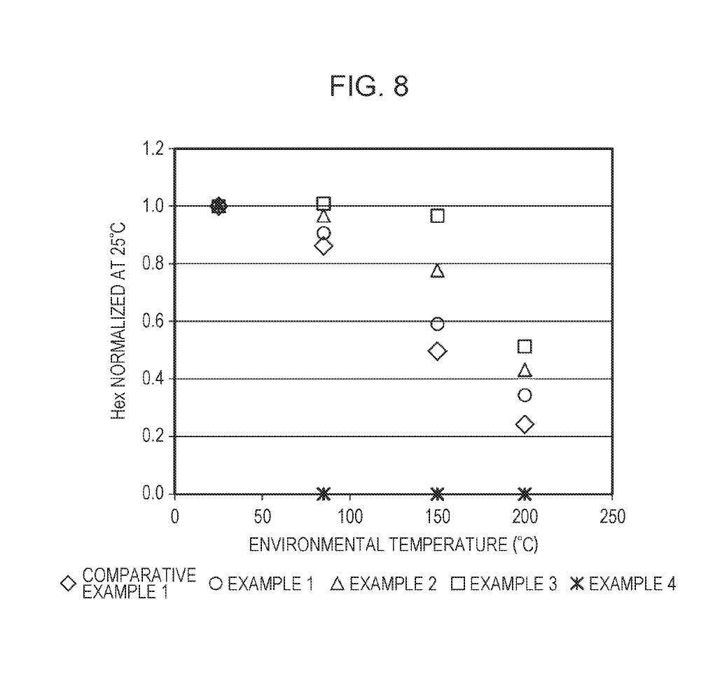

The exchange coupling bias Hex (unit: Oe) of each of the relative laminate structural body of Comparative Example 1 and the laminate structural bodies of Examples 1 to 4 was measured by changing an environmental temperature. The results are shown in Table 3. In addition, based on the results shown in Table 3, the relative value of the exchange coupling bias Hex obtained by normalization using the result at 25° C. is shown in Table 4, and the result obtained by plotting the data shown in Table 4 is shown in FIG. 8.

TABLE 3

| | 25° C. | 85° C. | 150° C. | 200° C. |
|---|---|---|---|---|
| Comparative | 42.10 | 36.30 | 20.91 | 10.20 |
| Example 1 | | | | |
| Example 1 | 39.80 | 36.07 | 23.50 | 13.66 |
| Example 2 | 40.04 | 38.72 | 31.10 | 17.28 |
| Example 3 | 41.37 | 41.75 | 39.98 | 21.18 |
| Example 4 | 41.81 | 0.00 | 0.00 | 0.00 |

TABLE 4

| | 25° C. | 85° C. | 150° C. | 200° C. |
|---|---|---|---|---|
| Comparative | 1 | 0.86 | 0.50 | 0.24 |
| Example 1 | | | | |
| Example 1 | 1 | 0.91 | 0.59 | 0.34 |
| Example 2 | 1 | 0.97 | 0.78 | 0.43 |
| Example 3 | 1 | 1.01 | 0.97 | 0.51 |
| Example 4 | 1 | 0.00 | 0.00 | 0.00 |

As shown in Tables 3 and 4 and FIG. 8, it was confirmed that the exchange coupling bias Hex of the laminate structural body according to each of Examples 1, 2, and 3 was higher in a high temperature environment than the exchange coupling bias Hex of the relative laminate structural body according to Comparative Example 1. That is, it was confirmed that by the adjustment of the composition of the magnetic adjustment layer, a magnetic sensor, the exchange coupling bias Hex of which was not likely to decrease even in a high temperature environment, could be obtained.

### Measurement Example 3

### Measurement of Zero-Magnetic Field Hysteresis

The zero-magnetic field hysteresis ZH (unit: %/FS) at 25° C. of each of the relative laminate structural body of Comparative Example 1 and the laminate structural bodies of Examples 1 to 4 was measured. The zero-magnetic field hysteresis ZH is the ratio of the magnitude (positive value-negative value of the hysteresis loop intersecting the y axis) of the output at a zero-magnetic field to the maximum value (positive output-negative output) of the output in a full-bridge output curve. The measurement results are shown in Table 5.

In addition, a zero-magnetic field hysteresis ZH1 was also measured after a high magnetic field (100 mT) was applied from the outside in a direction opposite to that of the exchange coupling bias, and an ability of forming a single magnetic domain state in the free magnetic layer by the exchange coupling bias was also confirmed. The measurement results are shown in Table 5. In addition, in Table 5, as Reference Example 1, the measurement result of the zero-magnetic field hysteresis ZH1 after the application of a high magnetic field is also shown which was obtained when the content of Pt in the magnetic adjustment layer was set to 60 percent by atom, and the thickness thereof was set to 500 Å.

TABLE 5

| | ZH | ZH1 |
|---|---|---|
| | (%/FS) | (%/FS) |
| Comparative | 0.24 | 0.27 |
| Example 1 | | |
| Example 1 | 0.28 | 0.31 |
| Example 2 | 0.25 | 0.28 |
| Example 3 | 0.25 | 0.28 |
| Example 4 | 0.25 | 8.27 |
| Reference | — | 8.75 |
| Example 1 | | |

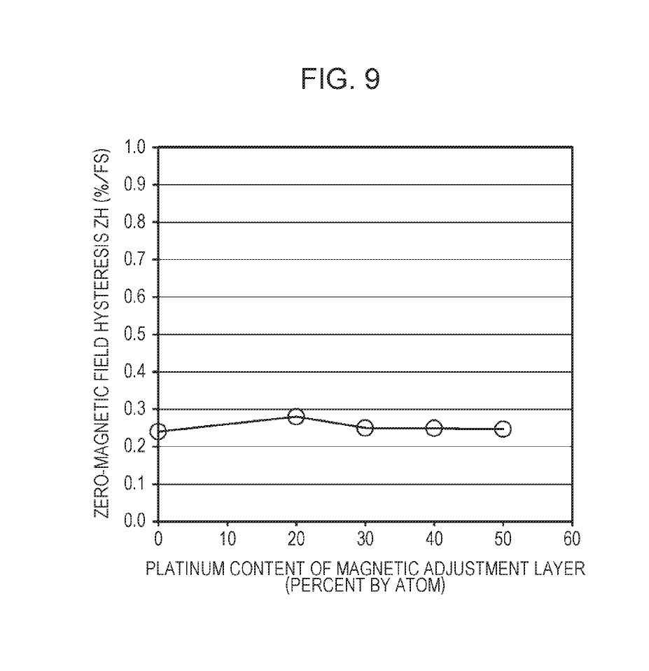

FIG. 9 is a graph showing the relationship between the zero-magnetic field hysteresis ZH and the platinum content of the magnetic adjustment layer. As shown in FIG. 9, it was confirmed that when the platinum content of the magnetic adjustment layer was changed, the change in zero-magnetic field hysteresis ZH was small, and that the measurement accuracy of the magnetic sensor was hardly influenced even when platinum was contained in the magnetic adjustment layer.

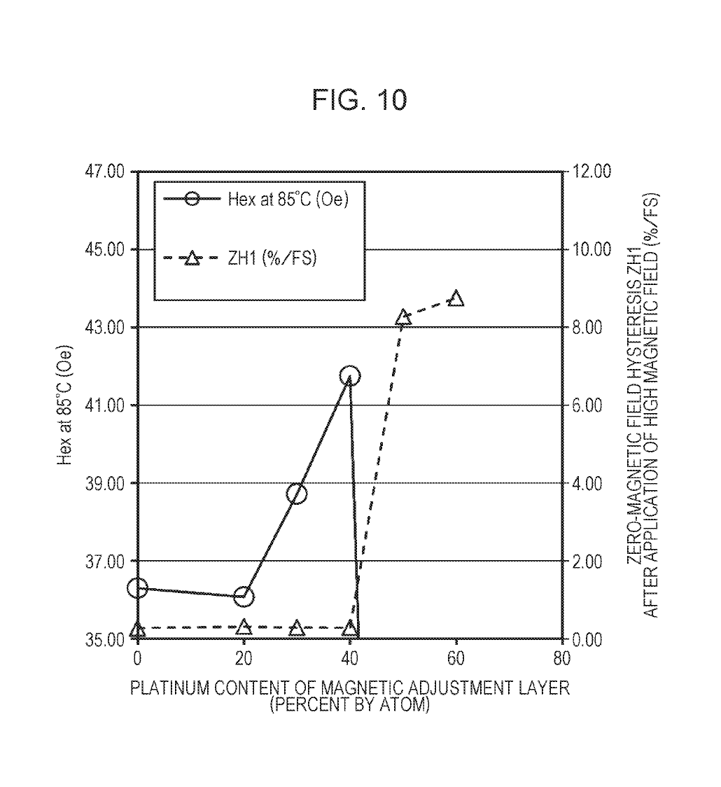

The relationship of the platinum content (unit: percent by atom) of the magnetic adjustment layer with the exchange coupling bias Hex (unit: Oe) at 85° C. and the zero-magnetic field hysteresis (unit: %/FS) after the application of a high magnetic field are collectively shown in Table 6 and FIG. 10.

TABLE 6

| | Pt | 85° C. | |
|---|---|---|---|
| | (Percent | Hex | ZH1 |
| | by atom) | (Oe) | (%/FS) |
| Comparative | 0 | 36.30 | 0.27 |
| Example 1 | | | |
| Example 1 | 20 | 36.07 | 0.31 |
| Example 2 | 30 | 38.72 | 0.28 |
| Example 3 | 40 | 41.75 | 0.28 |
| Example 4 | 50 | 0.00 | 8.27 |
| Reference | 60 | 0.00 | 8.75 |
| Example 1 | | | |

As shown in Table 6 and FIG. 10, it was confirmed that when the platinum content of the magnetic adjustment layer was more preferably set to 20 to 40 percent by atom, even in the case in which the magnetic sensor was used in a high temperature environment, the decrease in exchange coupling bias Hex could be particularly stably avoided.

As described above, in the magnetic sensors according to Examples, by increasing the platinum content of the magnetic adjustment layer, while the zero-magnetic field hysteresis ZH of the magnetic sensor is not substantially influenced, the Curie temperature Tcₐ of the magnetic adjustment layer can be decreased. Hence, it was confirmed that the magnetic sensor according to each of Examples 1, 2, and 3 was able to suppress the change in exchange coupling bias Hex with temperature while the generation of the zero-magnetic field hysteresis ZH was suppressed.

In addition, when the platinum content of the magnetic adjustment layer is 50 percent by atom or more, the magnetic adjustment layer is not likely to function as one element of the free magnetic layer, particularly in a high temperature environment, and the exchange coupling bias Hex is not likely to appropriately function. As a result, it was confirmed that the zero-magnetic field hysteresis ZH1 after the application of a high magnetic field was liable to increase.

A magnetic sensor including the magnetoresistive effect element according to one embodiment of the present invention is preferably used as a constituent element of a current sensor installed in transportation apparatuses, such as an electric car and a hybrid car, and infrastructure apparatuses, such as a pole transformer.

1. A magnetic sensor comprising:
a substrate:
a magnetoresistive effect element having a sensitivity axis in a specific direction, the magnetoresistive effect element including:
a laminate structure formed on the substrate, the laminated structure having a fixed magnetic layer, a free magnetic layer, and a nonmagnetic material layer interposed therebetween; and
a first antiferromangetic layer formed on the laminated structure and in contact with the free magnetic layer at an opposite side of the nonmagnetic material layer, the first antiferromagnetic layer generating an exchange coupling bias with the free magnetic layer and allowing a magnetization direction of the free magnetic layer to align with a predetermined direction when magnetization is changeable,
wherein the free magnetic layer includes:
a first ferromagnetic layer in contact with the first antiferromagnetic layer to have an exchange-coupling therewith; and
a magnetic adjustment layer provided on the first ferromagnetic layer at an opposite side of the first antiferromagnetic layer, the magnetic adjustment layer containing at least one iron group element and at least one platinum group element.

2. The magnetic sensor according to claim 1,
wherein a Curie temperature Tcₐ of the magnetic adjustment layer is lower than a Curie temperature Tc₁ of the first ferromagnetic layer.

3. The magnetic sensor according to claim 1,
wherein a reduction rate R_{Ms} of a saturation magnetization Ms of the magnetic adjustment layer obtained when the temperature thereof is increased from 25° C. to 150° C. is larger than a reduction rate R_{Ms0} of a saturation magnetization Ms of a reference layer obtained when the temperature thereof is increased from 25° C. to 150° C., the reference layer containing an iron group element in place of every corresponding platinum group element contained in the magnetic adjustment layer.

4. The magnetic sensor according to claim 1,
wherein the magnetic adjustment layer is formed of a material containing the platinum group element equal to or smaller than 40 percent by atom.

5. The magnetic sensor according to claim 1,
wherein the magnetic adjustment layer is formed of a material containing the platinum group element equal to or greater than 10 percent by atom.

6. The magnetic sensor according to claim 1,
wherein the free magnetic layer further includes:
a second ferromagnetic layer disposed on the magnetic adjustment layer at an opposite side of the first ferromagnetic layer.

7. The magnetic sensor according to claim 1,
wherein the nonmagnetic material layer contains Cu, and a surface of the free magnetic layer in contact with the nonmagnetic material layer is formed of a ferromagnetic material containing Co and Fe.

8. The magnetic sensor according to claim 1,
wherein the first antiferromagnetic layer contains a platinum group element and Mn.

9. The magnetic sensor according to claim 1,
wherein the first antiferromagnetic layer is formed of at least one of IrMn and PtMn.

10. The magnetic sensor according to claim 1,
wherein the fixed magnetic layer has a laminated structure including:
a first magnetic layers;
a second magnetic layer in contact with the nonmagnetic material layer; and
a nonmagnetic interlayer interposed between the first and second magnetic layers,
and wherein the fixed magnetic layer is a self-pinning type in which magnetization of the first magnetic layer and magnetization of the second magnetic layer are fixed in antiparallel to each other.

11. The magnetic sensor according to claim 1,
wherein the fixed magnetic layer has a laminated structure including:
a ferromagnetic layer in contact with the non magnetic material layer; and
a second antiferromagnetic layer disposed on the ferromagnetic layer at an opposite side of the nonmagnetic material layer, the second antiferromagnetic layer generating an exchange coupling bias with the ferromagnetic layer and allowing a magnetization direction of the ferromagnetic layer to align with a predetermined direction.

12. The magnetic sensor according to claim 1,
wherein in the laminate structure, the free magnetic layer is disposed between the fixed magnetic layer and the substrate.

13. The magnetic sensor according to claim 1,
wherein in the laminate structure, the fixed magnetic layer is disposed between the free magnetic layer and the substrate.

14. A current sensor comprising: the magnetic sensor according to claim 1.
